(19) United States
(12) Patent Application Publication
(10) Pub. No.: US 2025/0079328 A1
(43) Pub. Date: Mar. 6, 2025

(54) MOLDED CORE SUBSTRATE FOR EMBEDDING COMPONENTS

(71) Applicant: Advanced Micro Devices, Inc., Santa Clara, CA (US)

(72) Inventors: Deepak Vasant KULKARNI, Austin, TX (US); Sri Ranga Sai BOYAPATI, Austin, TX (US); Rajen Singh SIDHU, Portland, OR (US)

(21) Appl. No.: 18/242,991

(22) Filed: Sep. 6, 2023

(51) Int. Cl. H01L 23/538; H01L 21/56; H01L 23/00; H01L 23/31; H01L 25/16

(52) U.S. Cl. CPC H01L 23/5389; H01L 21/561; H01L 21/568; H01L 23/3128; H01L 24/24; H01L 24/25; H01L 24/82; H01L 25/16; H01L 2224/24137; H01L 2224/24195; H01L 2224/2518; H01L 2224/82106

(57) ABSTRACT

Active and passive electronic components are placed on a substrate and encapsulated with mold material to produce a molded core substrate for fabricating a hybrid integrated circuit (IC) device. A carrier has a release film laminated to a face thereof. A seed layer of copper is added over the release film and fiducials are plated onto the copper seed layer for component placement using alignment marks on the fiducials. Mold material is applied to the encapsulation layer and around and over the components. Mold material is ground planar with component tops. The carrier and release film are removed, leaving the copper seed layer exposed, which is etched to a pattern. Holes are formed in the mold material and then surfaces thereof are copper plated. A multilayer dielectric film is laminated over copper plating. Vias are formed in the multilayer dielectric film for connections to components.

### TECHNICAL FIELD

Embodiments of the present disclosure generally relate to integrated circuit packaging of active and passive electronic components, and in particular, to embedding the components in a molded core substrate of an integrated circuit package.

### BACKGROUND

Hybrid integrated circuit (IC) device packages incorporate both active components, e.g., transistors, oscillators, counters, registers, memory, integrated voltage regulator (IVR); and passive components, e.g., magnetic core inductors, deep trench capacitors and other passive components into a single IC device package. This IC device package may consist of a substrate, wherein the central region of that substrate is a fiber reinforced (FR4) core that is shaped in various fashions to accommodate placement of the components, provide electrical interconnections between the components therein and external connections thereto. After the components are installed and connected, the FR4 core with components connected therein may be encapsulated to produce the hybrid IC device package.

The electrical interconnections between the components may be through metal layers and traces, plated through holes (PTH) and conductive vias. External connections may be with contact pads exposed on the external surface(s) of the encapsulated substrate hybrid IC device package.

### SUMMARY

In one example of the disclosure, an integrated circuit (IC) molded core substrate, includes a plurality of components having circuit connections on first and/or second sides thereof. A mold material surrounds the plurality of components, wherein first and second surfaces of the mold material are coplanar with the circuit connections. A copper pattern interconnecting the circuit connections.

In one example of the disclosure, an integrated circuit (IC) includes a molded core substrate having a plurality of components having circuit connections on first and/or second sides thereof. A mold material surrounding the plurality of components, wherein first and second surfaces of the mold material are coplanar with the circuit connections. A copper pattern interconnecting the circuit connections. An IC package contains the IC molded core substrate. External connections on the IC package are coupled to the connections of the plurality of components in the molded core substrate.

In one example of the disclosure, a method for fabricating an integrated circuit (IC) molded core substrate includes using a carrier panel. Laminating a release film on a face of the carrier panel. Applying a first copper seed layer over the release film. Placing electronic components on the first copper seed layer. Applying mold material around and over the electronic components. Curing the mold material. Grinding the mold material planar with tops of the electronic components. Removing the release film with the carrier panel from the first copper seed layer. Etching the first copper seed layer. Forming holes in the cured mold material. Applying a second copper seed layer over the cured mold material and surfaces of the formed holes. Applying a copper blanket over the second copper seed layer and in the formed holes. Plugging the formed holes to produce plated through holes (PTH). Removing portions of the copper blanket but leaving other portions of the copper blanket for PTH and component connection pads. Laminating a multilayer dielectric film over the PTH and component connection pads. Forming vias through the laminated multilayer dielectric film to the PTH and the component connection pads.

### BRIEF DESCRIPTION OF THE DRAWINGS

So that the manner in which the above recited features of the present invention can be understood in detail, a more particular description of the invention, briefly summarized above, may be had by reference to examples, some of which are illustrated in the appended drawings. It is to be noted, however, that the appended drawings illustrate only typical examples of this invention and are therefore not to be considered limiting of its scope, for the invention may admit to other equally effective examples.

FIG. 1 illustrates a representative schematic elevational cross-section layout of a prior art hybrid integrated circuit (IC) device using a fiber reinforced (FR4) substrate core with components embedded therein.

FIG. 2 illustrates a representative schematic elevational cross-section layout of a molded core substrate with mold material encapsulating active and passive components used in a hybrid integrated circuit (IC) device, according to an example.

FIGS. 3A-3D, 4A, 4B, 5A-5C, 6A-6C, 7A-7C, and FIG. 8 illustrate schematic elevational cross-section layouts representative of process steps for forming the molded core substrate of the IC device of FIG. 2, according to examples.

FIG. 9 illustrates a schematic elevational cross-section layout representative of stacked molded core substrates, according to an example.

FIG. 10 illustrates a schematic elevational cross-section layout representative of the IC device of FIG. 2 in an integrated circuit package, according to an example.

To facilitate understanding, identical reference numerals have been used, where possible, to designate identical elements that are common to the figures, and a lower-case letter added where the elements are substantially the same. It is contemplated that elements of one embodiment may be beneficially incorporated in other embodiments.

### DETAILED DESCRIPTION

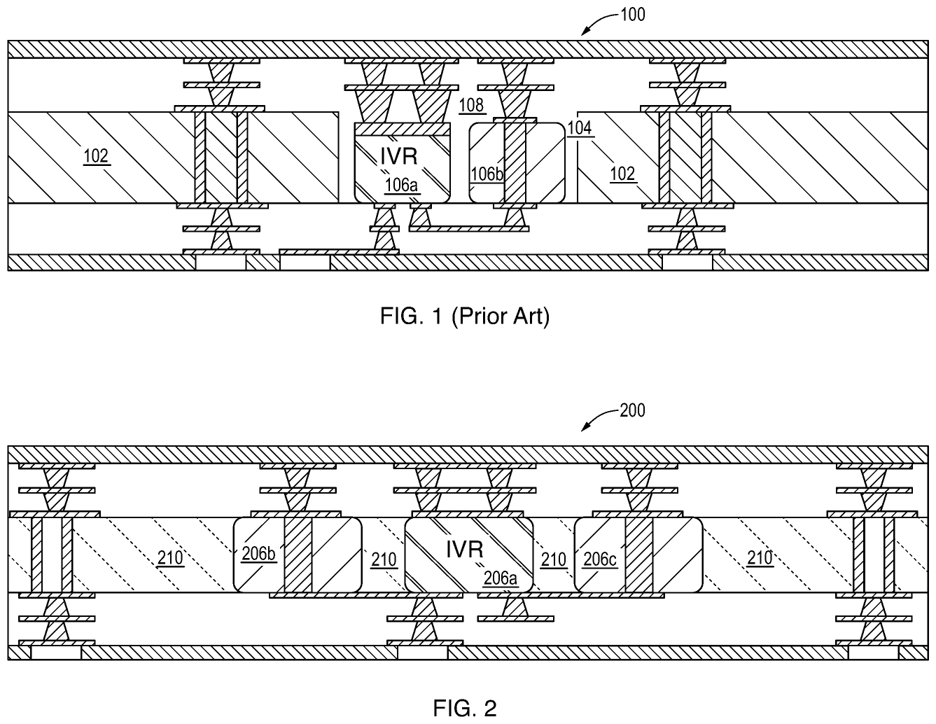

Referring to FIG. 1, depicted is a representative schematic elevational cross-section layout of a prior art hybrid integrated circuit (IC) device using a fiber reinforced (FR4) substrate core with components embedded therein. An integrated circuit (IC) device, generally represented by the numeral 100, has typically been manufactured using a fiber reinforced epoxy (FR4) core 102 that requires creating cavities 104 in the FR4 core for embedding (placement) of multiple components 106 therein. Then filling these cavities 104 with a dielectric 108 having a high coefficient of thermal expansion (CTE). Having multiple components 106 in one cavity 104 is challenging due to placement accuracy requirements and component shifting during the manufacturing process thereof.

Creating the cavities in the FR4 core material requires laser drilling (expensive) and the number of drilled cavities scales as a function of the number devices and components being embedded therein. Generally, a multilayer dielectric film is used to fill the cavity(ies). In one example, the multilayer dielectric film includes an organic build up film. In another example, the multilayer dielectric film includes adhesive coated polyester (PET) film. The adhesive coated polyester (PET) film may have a CTE of less than about 40 ppm/K at 150 degrees Celsius. In one example, the multilayer dielectric film is an ABF film. ABF-“Ajinomoto Build-up Film” is a trademark of Ajinomoto Co., Inc. When multilayer dielectric film (i.e., lamination) is used to fill a cavity, it creates undulation or thickness variations which creates non-uniformity in the dielectric thickness above the devices and components in the cavity. FR4 material derives its stiffness from the presence of glass fiber bundles. When these fibers are cut or removed to create cavities the overall stiffness of the core is weakened.

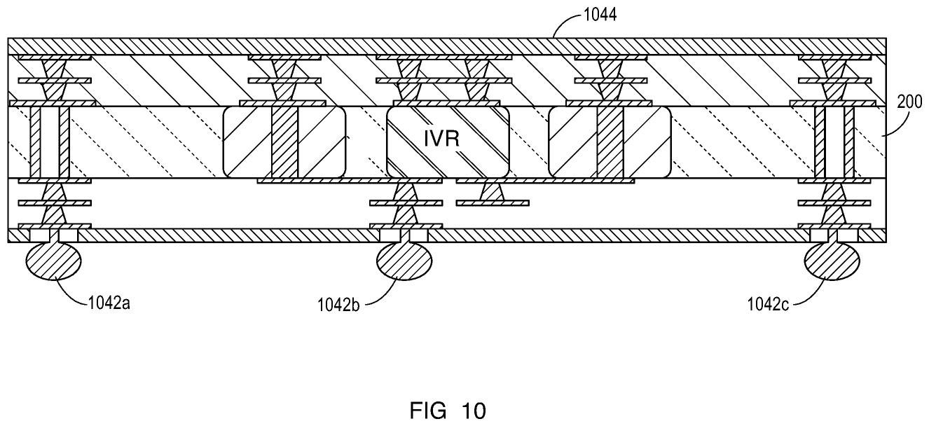

According to the teachings of this disclosure, a molded core substrate is used instead of a FR4 core in an IC device for installation in an IC package (FIG. 10). In contrast with the prior art use of a FR4 core that must be drilled to create cavities (subtractive process) for placement of electronic components therein and thereafter having to fill up these cavities containing the components. The molded core substrate has active and passive electronic components placed on a substrate and then these components are encapsulated with the mold materials (additive process). Use of a mold process enables embedding a large number of components, typically 50-100, in the molded core substrate. Using a molding process eliminates the necessity for a FR4 core and avoids the costly and technically challenging steps of creating cavities and filling the cavities in the FR4 substrate that the prior art IC device packaging required. Using a molded core substrate, instead of the current FR4 core, enables large scale integration of voltage regulators, inductors, deep trench capacitors and other active and passive electronic components into an easily manufactured and cost-effective IC products. A plurality of molded core substrates, each having active and passive electronic components, may be fabricated as a panel, encapsulated with the mold material, cured and then singulated into individual molded core substrates ready for incorporation into IC packages.

Various features are described hereinafter with reference to the drawing figures. It should be noted that the drawing figures may or may not be drawn to scale and that the elements of similar structures or functions are represented by like reference numerals throughout the drawing figures. It should be noted that the drawing figures are only intended to facilitate the description of the features of the examples. They are not intended as an exhaustive description of the examples below or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described. Referring now to the drawing figures, the details of examples are representative layouts schematically illustrated. Like elements in the drawing figures will be represented by like numbers, and similar elements will be represented by like numbers with a different lower-case letter suffix.

Referring to FIG. 2, depicted is a representative schematic elevational cross-section layout of a molded core substrate with mold material encapsulating electronic components used in a hybrid integrated circuit (IC) device, according to an example. A molded core substrate, generally represented by the numeral 200, may comprise a plurality of electronic components 206 encapsulated in mold material 210. The molded core substrate 200 may be used to fabricate a hybrid IC device package.

Benefits and advantages in using mold material to replace a FR4 core are: With a molded core substrate the mold material can be tuned to achieve a desired stiffness and coefficient of thermal expansion (CTE). There are substantially no dissimilarities in the CTE of the mold material across the entire device as experienced by a combination of the RF4 and cavity fill materials of the prior art. No expensive drilling of an unneeded FR4 core to form cavities. Using the molding process to embed components instead of drilling cavities in FR4 core and filling them with dielectric material (e.g., a multilayer dielectric film such as ABF). Use of mold grind processes to reveal conductive pads or bumps on components. Can leverage standard bumped wafer components instead of needing to customize the surface finish/pad geometry for embedding. Better thickness tolerance control due to placement of components on a carrier and relying on a mold grind process for uniformity of planar surfaces.

Advantages in using a molded core substrate are: Low CTE (a CTE of less than about 10 ppm/degree Celsius) and high stiffness compared to a fabrication process using an FR4 core, where the use of multilayer dielectric film for cavity filling increases the CTE of the composite core. Lower cost manufacturing processes that avoids the use of costly laser cavity drilling and laminators. Lower cost of materials compared to using multilayer dielectric film for cavity filling in an FR4 drilled core. Avoids difficulty of cavity fill with multilayer dielectric film or prepreg which may risk voids during the lamination process. More margin for die shifts during encapsulation of components. Better uniformity of vias and multilayer dielectric film thickness above components, mold and grind processes provide uniform core thickness and planarity. Ability to scale up to more components, which are limited using the prior art FR4 cavity drill and fill capacity. Mold material can be designed to achieve low CTE and high molded core substrate stiffness. Flexibility in the ability to have custom core thicknesses, instead of being forced to use approximately 200 micrometer increments available with FR4 core materials.

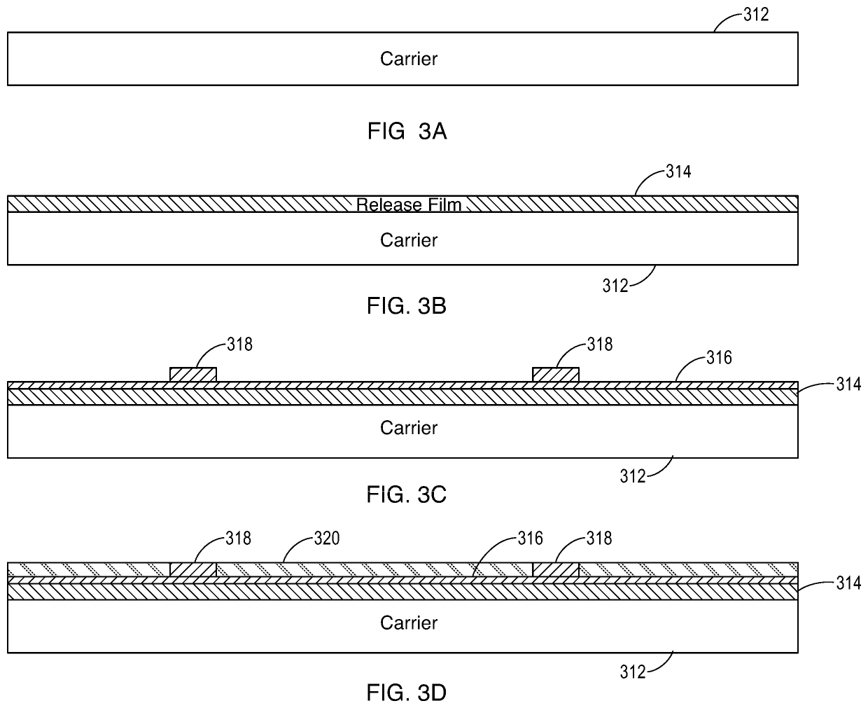

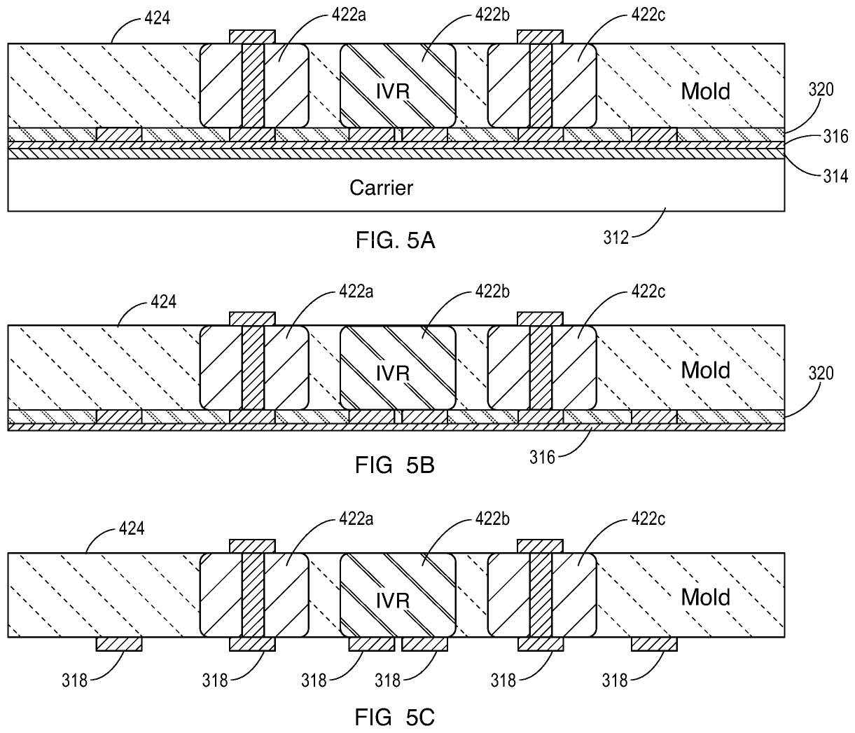

FIGS. 3A-3D, 4A, 4B, 5A-5C, 6A-6C, 7A-7C, and FIG. 8 illustrate schematic elevational cross-section layouts representative of process steps for forming the molded core substrate of the IC device of FIG. 2, according to examples. The process for manufacturing a molded core substrate 200 for use in a hybrid IC device, according to the teaching of this disclosure, may start with a carrier panel 312 (FIG. 3A). The carrier panel 312 may be, for example but is not limited to, a glass, ceramic or metal substrate. Stainless steel/metal with thermal release film may also be used. A release film 314 may be laminated onto a face of the carrier panel 312 (FIG. 3B). The release film 314 may be used to de-bond the carrier panel 312 from the molded core substrate 200 in a subsequent manufacturing step (FIG. 5B).

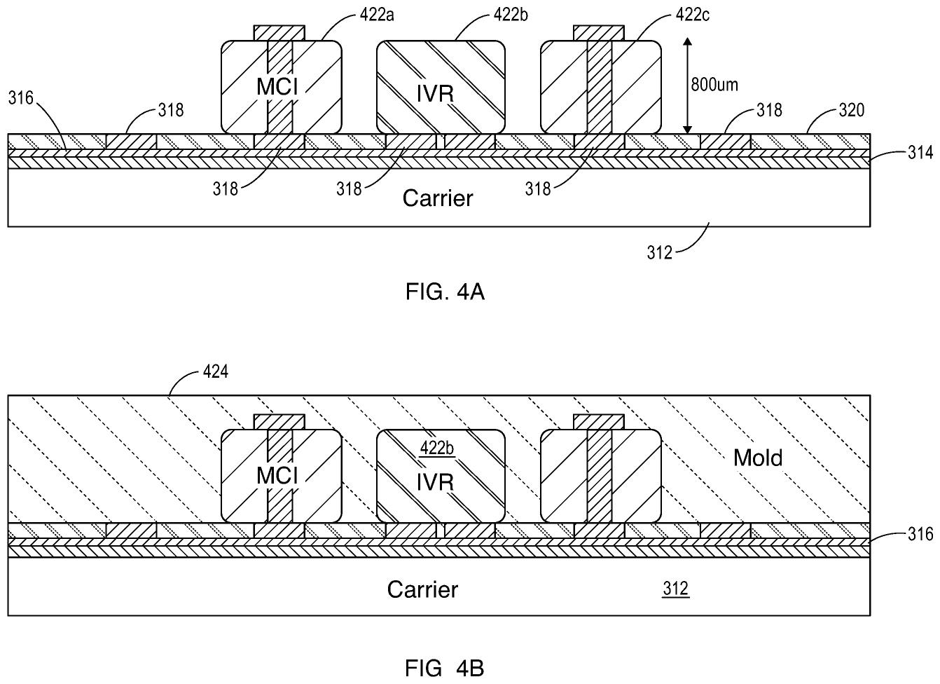

A copper seed layer 316 and fiducials 318 are added onto a face of the release film 314 (FIG. 3C). The fiducials 318 are used to facilitate component placement accuracy on the copper seed layer 316. Optionally an encapsulation layer 320 may be added over the copper seed layer 316 and may be planarized with the fiducials 318 (FIG. 3D). Components 422 may be accurately placed using, for example but not limited to, alignment marks on the copper seed layer 316 (FIG. 4A), e.g., using the fiducials 318. After the components 422 are attached to the copper seed layer 316, mold material 424 may be used to encapsulate the components 422 (FIG. 4B). The mold material 424, e.g., an epoxy/filler composite, may have a low coefficient of thermal expansion (CTE) and high modulus to replicate a traditional core. The mold material may be formed in a compression mold.

Once cured, the mold material 424 may be ground to expose a top side of the components 422 (FIG. 5A). The mold grind may be planar with the top of the components 422. Next the carrier panel 312 may be removed by de-bonding the release film 314 from the copper seed layer 316 (FIG. 5B) using, for example but is not limited to, a laser, thermal release and photo-induced ultra violet curing. The copper seed layer 316 may be etched and then the encapsulation layer 320 may be removed with a solvent clean to expose the bottoms of the components 422 (connections 522) and fiducials 318 (FIG. 5C).

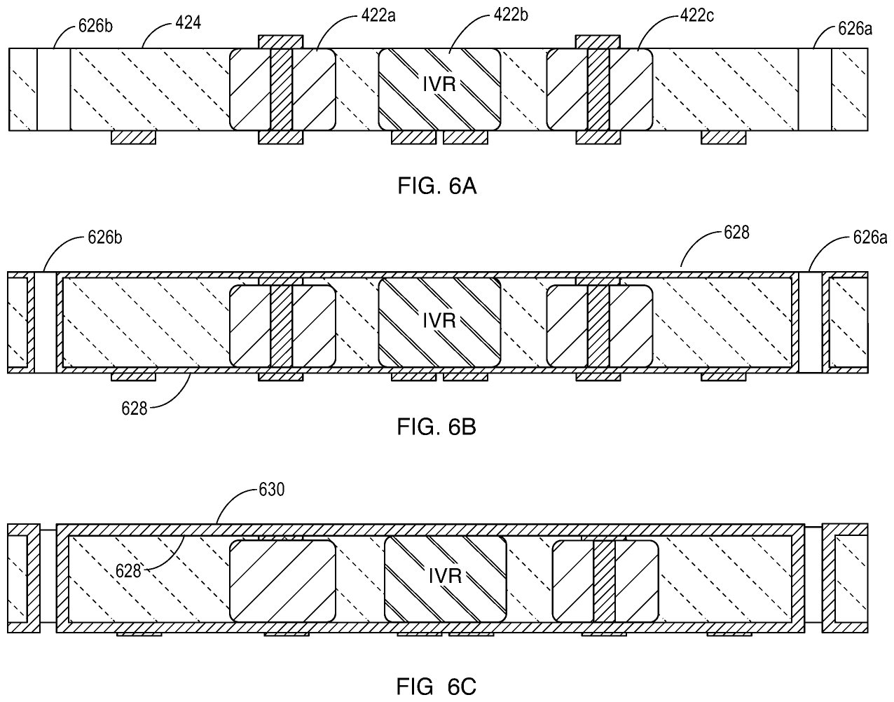

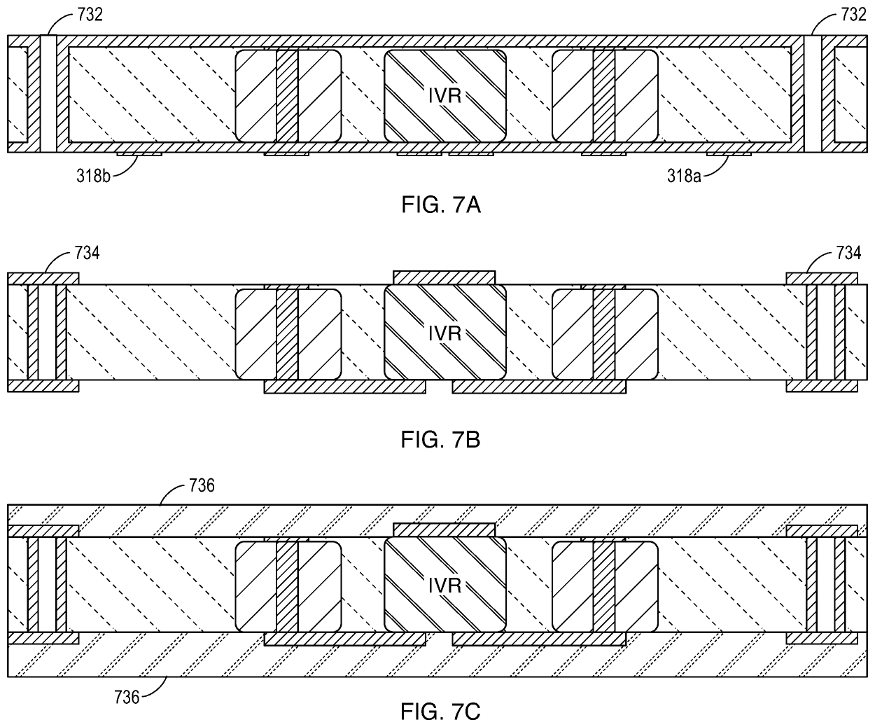

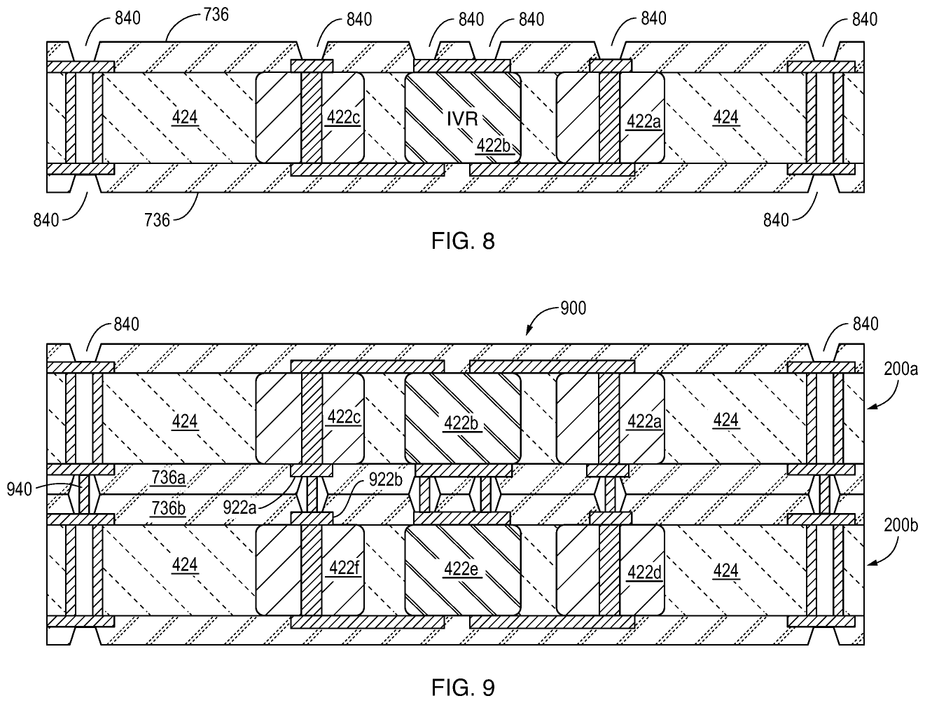

Holes 626 may be formed in the cured mold material 424 for forming vias (FIG. 6A). The holes 626 may be formed by drilling, cutting with a laser, or other suitable technique. A seed layer of copper 628 may be formed on the top and bottom of the mold material 424, and inside of the holes 626 for forming plated through holes (PTH) (FIG. 6B). A copper blanket 630 may be electroplated onto the seed layer of copper 628 and into the holes 626 (FIG. 6C) to assist in the further step of grinding plugs 732 to planarize them with the copper blanket 630. The Plugs 732 may be formed with organic resin, paste printing or liquid dispensing in the holes 626 and the copper blanket 630 may be connected to the PTH pads 734 formed after subtractive etching of the copper blanket 630. The fiducials 318, used for placement accuracy of components, may be removed during the subtractive etching because they are no longer needed (FIG. 7B). A multilayer dielectric film 736 may be laminated on the top and bottom surfaces of the mold material 424 (FIG. 7C). Thereafter, vias 840 may be formed in the multilayer dielectric film 736 for external connections to the components 422 of the mold material 424 during a substrate manufacturing process (FIG. 8).

Referring to FIG. 9, depicted is a schematic elevational cross-section layout representative of stacked molded core substrates, according to an example. Stacked molded core substrates, generally represented by the numeral 900, may comprise at least two molded core substrates 200 (two shown), each may comprise a plurality of electronic components 206 encapsulated in mold material 210. The stacked molded core substrates 900 may be used to fabricate a higher density hybrid IC device package since more components may be accommodated on a smaller horizontal footprint. Component connection pads 922 of each of the at least two molded core substrates 200 may be interconnected with connections 940, e.g., standard metallization and lithography processes, and external connections 1042 (FIG. 10) made through the vias 840. Further standard manufacturing processes may be used to package the molded core substrates 200 and/or 900 into hybrid IC device products.

Referring to FIG. 10, depicted is a schematic elevational cross-section layout representative of the IC device of FIG. 2 in an integrated circuit package, according to an example. The IC molded core substrate 200 with components 206 therein are fabricated in an IC package 1044. The IC package 1044 has external connections 1042, for example but not limited to ball grid array, land grid array, pin grid array, coupled to the component connections of the IC molded core substrate 200.

As will be appreciated by one skilled in the art and having the benefit of this disclosure, the embodiments disclosed herein may be embodied as a system, method, apparatus, or computer programmed product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

While the foregoing is directed to embodiments of the present invention, other and further embodiments of the invention may be devised without departing from the basic scope thereof, and the scope thereof is determined by the claims that follow.

What is claimed is:

1. An integrated circuit (IC) molded core substrate, comprising:
a plurality of components having circuit connections on first and/or second sides thereof;
mold material surrounding the plurality of components, wherein first and second surfaces of the mold material are coplanar with the circuit connections; and
a copper pattern interconnecting the circuit connections.

2. The IC molded core substrate according to claim 1, wherein the mold material has a low coefficient of thermal expansion (CTE).

3. The IC molded core substrate according to claim 1, wherein the mold material is formed in a compression mold.

4. The IC molded core substrate according to claim 1, wherein the plurality of components are selected from the group consisting of an integrated voltage regulator, an inductor and a deep trench capacitor.

5. The IC molded core substrate according to claim 1, further comprising plated through holes in the mold material from the first surface to the second surface thereof.

6. The IC molded core substrate according to claim 1, further comprising multilayer dielectric film including an adhesive coated polyester layer laminated to the first and second surfaces of the mold material.

7. The IC molded core substrate according to claim 6, further comprising vias in the multilayer dielectric film laminated to the first and/or second surfaces of the mold material.

8. The IC molded core substrate according to claim 7, wherein connections to the plurality of components in the molded core substrate are made through the vias.

9. An integrated circuit (IC), comprising:
a molded core substrate having
a plurality of components having circuit connections on first and/or second sides thereof,
mold material surrounding the plurality of components, wherein first and second surfaces of the mold material are coplanar with the circuit connections, and
a copper pattern interconnecting the circuit connections;
an IC package containing the IC molded core substrate; and
external connections on the IC package coupled to the circuit connections of the plurality of components in the molded core substrate.

10. The IC according to claim 9, wherein the IC package contains at least two molded core substrates.

11. The IC according to claim 9, wherein the external connections on the IC package are selected from the group consisting of ball grid array, land grid array and pin grid array.

12. A method for fabricating an integrated circuit (IC) molded core substrate, comprising:
laminating a release film on a face of a carrier panel;
applying a first copper seed layer over the release film;
placing electronic components on the first copper seed layer;
applying mold material around and over the electronic components;
curing the mold material;
grinding the mold material planar with tops of the electronic components;
removing the release film with the carrier panel from the first copper seed layer;
etching the first copper seed layer;
forming holes in the mold material;
applying a second copper seed layer over the cured mold material and formed hole surfaces;
applying a copper blanket over the second copper seed layer and in the formed holes;
plugging the formed holes to produce plated through holes (PTH);
removing portions of the copper blanket but leaving other portions of the copper blanket for PTH and component connection pads;
laminating multilayer dielectric film over the PTH and component connection pads; and
forming vias through the multilayer dielectric film to the PTH and the component connection pads.

13. The method according to claim 12, wherein the carrier panel is selected from any one of the group consisting of a glass substrate, a ceramic substrate and a metal substrate.

14. The method according to claim 12, wherein the step of removing the carrier panel from the molded core substrate comprises de-bonding the release film from the first copper seed layer.

15. The method according to claim 14, wherein de-bonding the release film from the first copper seed layer is done with a laser.

16. The method according to claim 14, wherein de-bonding the release film from the first copper seed layer is done by thermal release.

17. The method according to claim 14, wherein t de-bonding the release film from the first copper seed layer is done by photo-induced ultra violet curing.

18. The method according to claim 12, wherein the copper blanket is applied over the second copper seed layer and in the formed holes by electroplating.

19. The method according to claim 12, further comprising the step of plating fiducials, having alignment marks thereon, onto the first copper seed layer for the placing of electronic component using the alignment marks of the fiducials.

20. The method according to claim 19, further comprising the step of removing the fiducials with subtractive etching after placement of the electronic components.
